(19) United States
(12) Patent Application Publication
(10) Pub. No.: US 2015/0289365 A1
(43) Pub. Date: Oct. 8, 2015

(54) Circuit Carrier With Interior Plating Lines and Peripheral Shielding

(71) Applicant: Apple Inc., Cupertino, CA (US)

(72) Inventors: Christopher V. Hunat, SINGAPORE (SG); Annabelle Q. Yang, SINGAPORE (SG)

(73) Assignee: Apple Inc., Cupertino, CA (US)

(21) Appl. No.: 14/247,530

(22) Filed: Apr. 8, 2014

(51) Int. Cl. H05K 1/02; H05K 1/03; H01L 23/552; H01L 27/146; H01L 23/498

(52) U.S. Cl. CPC H05K 1/0284; H01L 27/14634; H01L 27/14636; H01L 23/49894; H01L 23/49838; H01L 23/552; H05K 1/0306; H05K 1/0216; H05K 2201/0195; H05K 2201/09036

(57) ABSTRACT

A dielectric substrate may serve as a circuit carrier for integrated circuits and other electrical components. The dielectric substrate may be formed from a dielectric material such as a ceramic substrate material, a printed circuit board substrate material, or other substrate material. The dielectric substrate may have a rectangular outline with four peripheral edge surfaces. The dielectric material may contain multiple layers that are laminated together and may support metal traces forming contacts and other interconnects. Integrated circuits and other electrical components may be mounted to the contacts. The metal traces may include electroplating lines that extend inwardly. The dielectric material may have a rectangular ring shape with a central rectangular opening having inner edge surfaces. The electroplating lines may be exposed along the inner edge surfaces. The four peripheral edge surfaces may be provided with a conductive electromagnetic interference shielding layer.

### BACKGROUND

This relates generally to circuit carriers and, more particularly, to dielectric substrates to which electrical components may be mounted.

Electrical components such as integrated circuits are often mounted on substrates such as printed circuit boards, flexible printed circuits, and ceramic substrates. Substrates such as these contain interconnects that are used to interconnect the components with each other and with external circuitry.

It can be challenging to form substrates that exhibit desired performance characteristics. Metal traces on dielectric substrates are often formed using electroplating techniques. Plating bus lines in a substrate are routed to contact points on a sheet of substrate material. The sheet of substrate material is immersed in a plating bath. During electroplating, a cathode is coupled to the plating bus lines and an anode is coupled to the plating bath.

The sheet of substrate material is singulated after plating operations are complete. This can expose portions of the plating bus lines around the outer edges of the substrate. When high-frequency signals are applied to the interconnects in the substrate during operation in a system, electromagnetic interference signals can escape through the exposed portions of the plating bus lines. Electromagnetic interference can disrupt a system in which the circuitry on the substrate is being used.

It would therefore be desirable to be able to provide improved substrates for mounting electrical components.

### SUMMARY

A dielectric substrate may serve as a circuit carrier for integrated circuits and other electrical components. For example, an integrated circuit such as an image sensor integrated circuit may be mounted to the dielectric substrate. The dielectric substrate may have an opening that allows light to pass to the image sensor integrated circuit. Integrated circuits and other electrical components that are used by the image sensor integrated circuit may be mounted to the dielectric substrate.

The dielectric substrate may be formed from a dielectric material such as a ceramic substrate material, a printed circuit board substrate material, or a flexible printed circuit substrate material. The dielectric substrate may have a rectangular outline with four peripheral edge surfaces. The dielectric material may contain multiple layers that are laminated together and may support metal traces that form contacts and other interconnects.

The integrated circuits and other electrical components on the substrate may be soldered to the contacts. The metal traces may include electroplating lines that extend inwardly. The opening may have inner edge surfaces. The electroplating lines may be exposed along the inner edge surfaces. An electrode in an electroplating system may contact the electroplating lines during electroplating operations.

The four peripheral edge surfaces run around the four sides of the dielectric substrate and may be provided with a conductive electromagnetic interference shielding layer.

### BRIEF DESCRIPTION OF THE DRAWINGS

FIG. 1 is a perspective view of an illustrative substrate having an electromagnetic interference shield and an interior opening with exposed plating bus lines in accordance with an embodiment.

FIG. 2 is a cross-sectional side view of an illustrative multilayer substrate in accordance with an embodiment.

FIG. 3 is a cross-sectional side view of an illustrative electrical component mounted on a substrate that is mounted to a printed circuit with solder connections in accordance with an embodiment.

FIG. 4 is a cross-sectional side view of an illustrative electroplating bath being used to electroplate metal traces on a sheet of dielectric substrate material in accordance with an embodiment.

FIG. 5 is a perspective view of an illustrative substrate dielectric structure having inwardly-facing exposed plating bus lines being contacted by an electroplating cathode structure in accordance with an embodiment.

FIG. 6 is a diagram of substrate being coated with a conductive layer that forms an electromagnetic interference shield around the peripheral edge of the substrate in accordance with an embodiment.

FIG. 7 is a flow chart of illustrative steps involved in forming substrates with electromagnetic shielding and in assembling the substrates into a system in accordance with an embodiment.

### DETAILED DESCRIPTION

Electrical components are often mounted on circuit carrier substrates. For example, an integrated circuit such as an image sensor integrated circuit may be mounted on dielectric substrate having the shape of a rectangular ring. Support circuits such as additional integrated circuits, discrete components such as inductors, capacitors, and resistors, switches, and other electrical components may be mounted to the substrate in the vicinity of the image sensor integrated circuit. The dielectric of the substrate may be ceramic or other dielectric material.

To interconnect the circuitry that is mounted to a substrate, metal traces are incorporated into the substrate. The metal traces may include vertical connections (vias) and horizontally extending signal lines. Metal traces on the surfaces of the substrate may form solder pads or other contacts. The metal traces form interconnects that route signals between the circuitry on the substrate and external circuitry. The external circuitry may be coupled to the substrate using a printed circuit. For example, an integrated circuit and the substrate to which the integrated circuit is mounted may be soldered to a rigid printed circuit board or a flexible printed circuit.

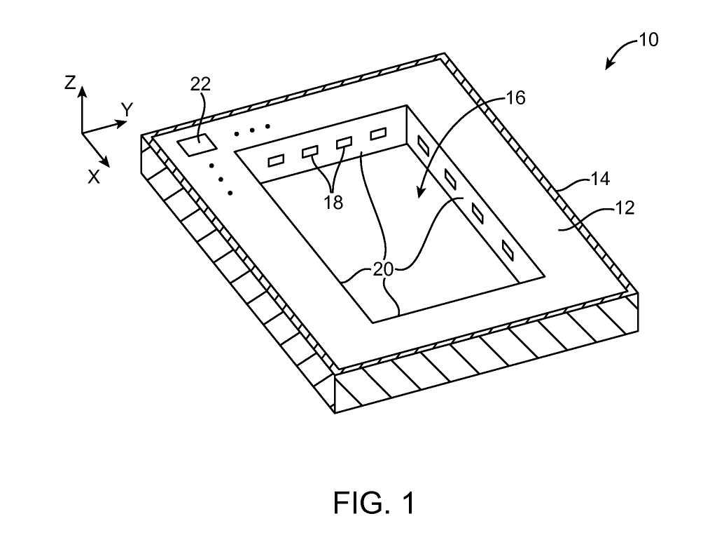

FIG. 1 is a perspective view of an illustrative circuit carrier substrate to which an integrated circuit such as an image sensor integrated circuit may be mounted. As shown in FIG. 1, substrate 10 may have contacts such as contacts 22 on a ring-shaped ceramic structure or other dielectric structure such as structure 12. Integrated circuits, discrete components, and other circuitry may be mounted to contacts 22 using solder or other conductive material. Circuit carrier substrate 10 serves as a carrier for this circuitry and may sometimes be referred to as a carrier, a circuit carrier, a carrier substrate, a circuit substrate, or a substrate.

As shown in FIG. 1, dielectric structure 12 of substrate 10 may have a rectangular outline when viewed from above (i.e., substrate 10 may be rectangular in the X-Y plane of FIG. 1). In general, substrate 10 may be a rigid printed circuit board substrate material (e.g., a dielectric structure formed from a rigid printed circuit board material such as fiberglass-filled epoxy), a flexible printed circuit (i.e., a printed circuit formed from one or more a flexible polymer layers such as one or more flexible polyimide layers), a ceramic substrate (e.g., a substrate formed from multiple layers of ceramic substrate material and metal traces), or other suitable dielectric substrate. Ceramic substrates may be formed from alumina or other ceramic materials. Configurations in which substrate 10 is a ceramic substrate are sometimes described herein as an example. This is, however, merely illustrative. Any suitable dielectric may be used in forming a circuit carrier substrate, if desired.

One or more layers of dielectric (e.g., a ceramic such as alumina) may be used in forming substrate 10. Contacts 22, which may sometimes be referred to as solder pads or contact pads, may be formed from metal traces that are supported by the dielectric material of substrate 10. For example, contacts 22 may be formed on the exposed upper surface of substrate 10. Contacts 22 may also be formed on the opposing lower surface of substrate 10 and, if desired, on a ledge formed from a recessed portion of substrate 10. Substrate 10 may have one or more openings such as illustrative rectangular central opening 16.

During plating operations, it is necessary for electrical current to be applied to the metal traces of substrate 10. Plating bus lines (sometimes referred to as electroplating bus lines, electroplating lines, or plating lines) may be used to short the metal traces in substrate 10 to one or more plating contact points on a sheet of substrate material. A cathode structure may be placed in contact with each plating contact point while the sheet of substrate material is immersed in an electroplating bath. A corresponding anode structure may be placed in the electroplating bath to complete an electroplating circuit.

The metal traces for multiple substrates can be electroplated simultaneously by using a sheet of substrate material that is large enough to form numerous substrates. The sheet of substrate material may be, for example, a ceramic sheet such as an alumina sheet having multiple alumina sublayers. Following electroplating, the sheet of substrate material may be singulated. The singulation process involves dicing up the ceramic sheet to form individual rectangular substrates such as substrate 10 of FIG. 1. Following singulation, conductive coating 14 may be placed on the exposed peripheral edges of substrate 10 to serve as electromagnetic interference shielding.

To prevent the plating bus lines in substrate 10 from being shorted together in substrate 10, the plating bus lines are preferably not routed outwardly (i.e., the plating bus lines on the sheet of substrate material do not extend laterally outwards from the rectangular footprint of substrate 10 in the X-Y plane). Rather, the plating bus lines extend inwardly towards opening 16 and are exposed along inner edge surface 20 of opening 16, as shown by illustrative plating bus lines 18 of FIG. 1.

Because plating bus lines 18 are exposed on the surface of inner edge 20 of substrate 10 (i.e., on one or more of the inner surfaces of the inner rectangular opening 16 in rectangular ring-shaped ceramic structure 12), a cathode structure in an electroplating apparatus may make contact with plating bus lines 18 during electroplating operations. Because plating bus lines 18 need not extend outwardly to be contacted by the cathode, the outer edge of ceramic structure 12 can be left free of plating bus lines. As a result, a metal layer or other conductive coating such as conductive coating 14 may be formed on the peripheral edge surfaces that form the four outer sides of substrate 10 without shorting together any plating bus lines (and without shorting together any contacts 22 or other metal traces that remain coupled to the plating bus lines after singulation). Metal layer 14 may serve as an electromagnetic interference shield that blocks electromagnetic interference that might otherwise be emitted by the traces in substrate 10 during operation of the circuitry coupled to substrate 10.

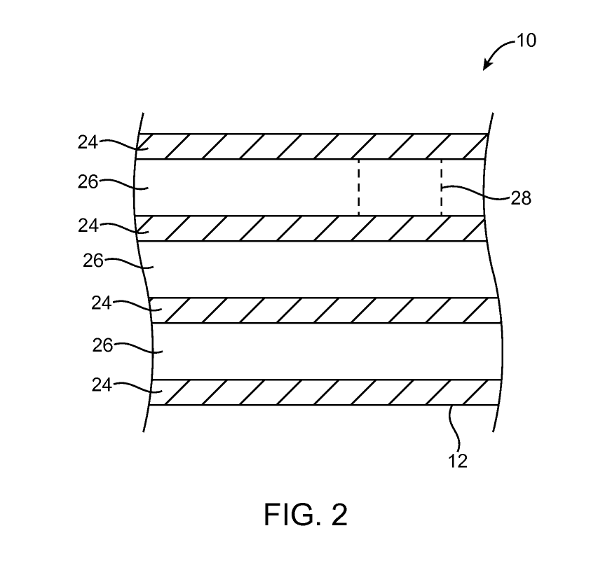

FIG. 2 is a cross-sectional side view of one of the side portions of rectangular ring-shaped ceramic structure 12 of substrate 10 in FIG. 1. As shown in FIG. 2, ceramic structure 12 may include one or more metal layers 24 and one or more ceramic layers 26. Ceramic layers 26 may be formed from alumina or other ceramic materials. Metal layers 24 may be formed from copper, other metals, or metals that are alloys of more than one elemental metal. Metal layers 24 may be patterned to form metal traces that serve as contact pads, signal lines, and other interconnects in substrate 10. Ceramic layers 26 support the metal traces and electrically isolate metal traces from each other.

The interconnects of substrate 10 may also include vias such as illustrative via 28. Vias such as via 28 may contain metal (e.g., copper, etc.) and can be used to short together traces in different respective metal layers 24. For example, a via may be used to electrically couple a metal trace such as a contact pad on the upper surface of substrate 10 to a metal layer that is embedded between a pair of respective ceramic layers 26. There are four metal layers 24 and three interposed ceramic layers 26 in the configuration of FIG. 2. This is merely illustrative. There may be one or more ceramic layers 26 in substrate 10, two or more ceramic layers 26 in substrate 10, or three or more ceramic layers 26 in substrate 10, and there may be one or more metal layers 24 in substrate 10, two or more metal layers 24 in substrate 10, three or more metal layers 24 in substrate 10, or four or more metal layers 24 in substrate 10. Adhesive may be used in laminating layers together or the metal and/or dielectric layers of substrate 10 may be laminated together without adhesive. The configuration of FIG. 2 in which four metal layers and three ceramic layers are laminated together without interposed adhesive layers is shown as an example. Vias 28 may be used in connecting the metal traces of metal layers 24 of substrate 10 together (e.g., to couple the metal traces of the uppermost layer to the next-to-uppermost layer, to couple the metal traces of the bottommost layer to the next-to-bottommost layer, to couple metal traces associated with interior metal layers together, etc.).

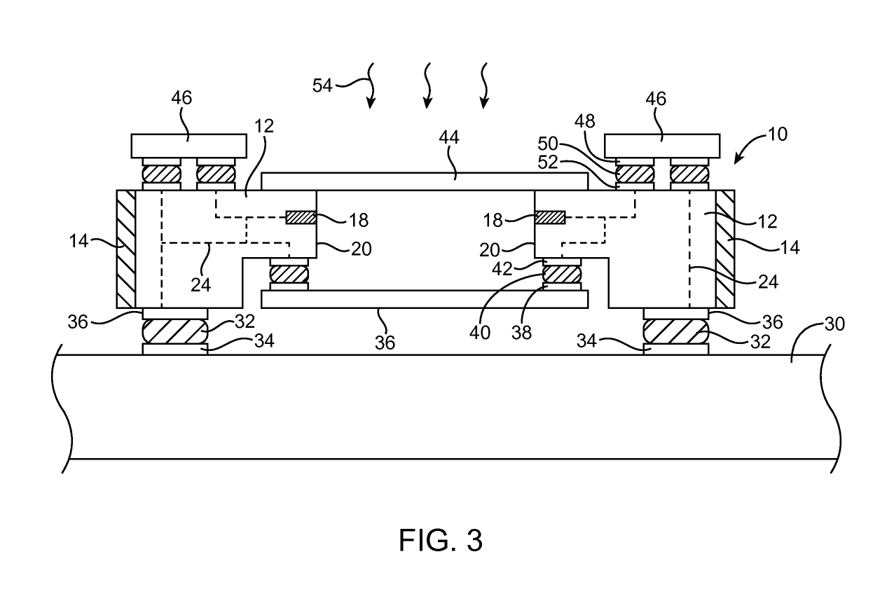

A cross-sectional side view of substrate 10 in a configuration in which substrate 10 is being used as a support for an integrated circuit and in which substrate 10 is mounted on a printed circuit is shown in FIG. 3. As shown in FIG. 3, substrate 10 may be mounted on a substrate such as printed circuit 30. Printed circuit 30 may be a rigid printed circuit board (e.g., a printed circuit board formed from a rigid printed circuit board material such as fiberglass-filled epoxy), may be formed from a flexible printed circuit (e.g., a printed circuit formed from a flexible sheet of polyimide or a layer of another polymer), or may be formed from other substrate material (e.g., ceramic, a molded plastic carrier, etc.). Printed circuit 30 may have contacts 34 that are connected to metal traces forming a set of printed circuit board interconnects. Solder 32 may be used to solder contacts 36 on the lower surface of substrate 10 to contacts 34.

Contacts 36 on substrate 10 may form part of a network of interconnects formed within substrate 10. Contacts 36 may, for example, be coupled to metal traces 24 that route signals between contacts 36 and other metal traces in substrate 10 such as metal traces that form plating bus lines 18, metal traces that form contacts 52 on the upper surface of substrate 10, metal traces that are connected to contacts 20 near the lower surface of substrate 10, etc.

Substrate 10 may have a recessed portion forming a ledge and recess to accommodate integrated circuit 36. Integrated circuit 36 may be mounted to substrate 10 by using solder 40 to couple contacts 38 on integrated circuit 36 to contacts 20 on substrate 10. A transparent member such as glass layer 44 may be mounted over the central opening in substrate 10. Integrated circuit 36 may be mounted over the bottom of the central opening. In this configuration, incoming light 54 from an object may pass through transparent member 44 and may be received by integrated circuit 36. Integrated circuit 36 may be a digital image sensor that coverts light into digital images. Circuitry 46 such as discrete components and/or additional integrated circuits may be mounted to substrate 10 by coupling contacts 48 on circuits 46 to contacts 52 on substrate 10 using solder 50. The interconnects formed by the metal traces in substrate 10 may route signals between circuitry 46, circuitry 36, and the interconnects of printed circuit 30.

A conductive coating such as metal layer 14 may be formed on the peripheral (outer) edge surfaces of substrate 10 (i.e., on the peripheral edge surfaces of ceramic member 12 running along the four sides of substrate 10), as shown in FIG. 3. Metal layer 14 serves as electromagnetic interference shielding that blocks electromagnetic interference that would otherwise exit the sides of substrate 10.

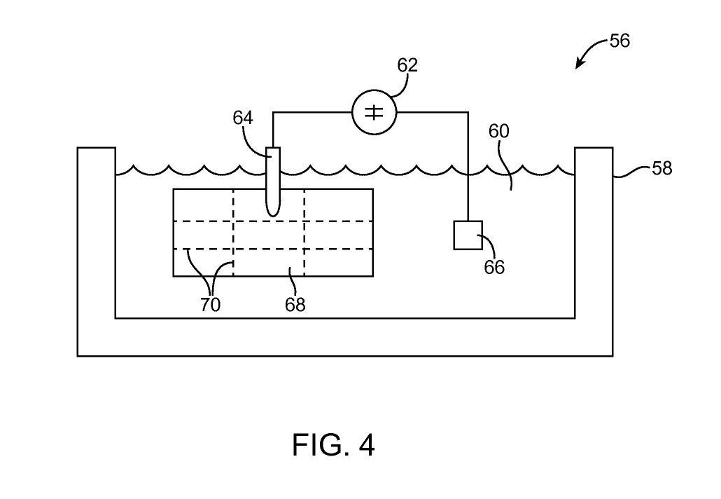

An illustrative electroplating system that may be used in electroplating metal traces in substrate 10 (e.g., a system that may be used in electroplating copper, nickel, gold, and/or other metals onto exposed traces such as contacts on the upper and lower surfaces of substrate 10) is shown in FIG. 4. As shown in FIG. 4, electroplating system 56 includes electroplating bath 60 in vessel 58. Anode 66 is immersed in electroplating bath 60. Cathode 64 contacts plating lines such as plating bus lines 18. Lines 18 are coupled to the other metal traces of substrate 10. Current source 62 applies current to cathode 64 and anode 66 that runs through bath 60 and plates metal onto exposed metal traces in bath 60. During electroplating, substrate 10 is part of a large sheet of ceramic substrate material such as ceramic sheet 68. After electroplating, individual substrates such as substrate 10 may be cut from sheet 68 by cutting up sheet 68 along dicing lines 70 (e.g., by using a saw or other cutting equipment to singulate individual substrates from ceramic sheet 68).

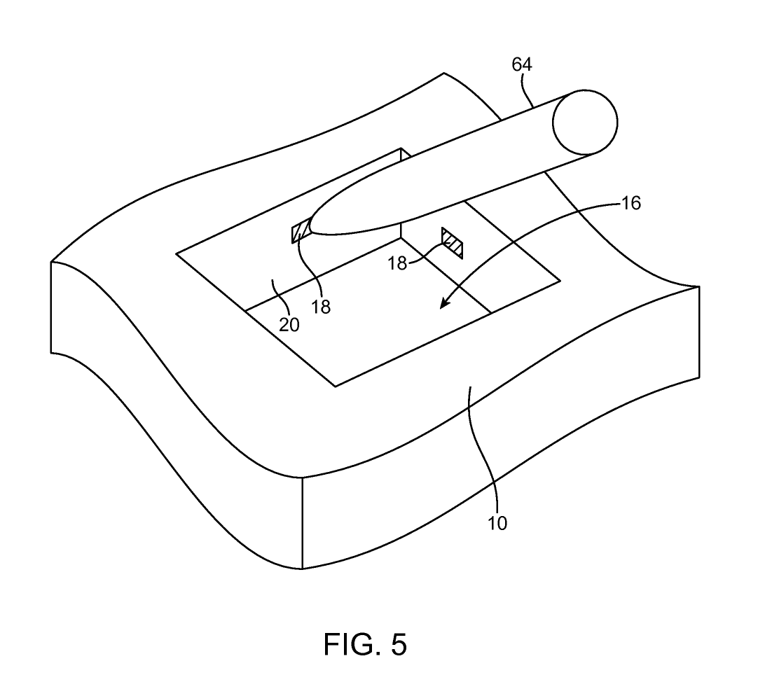

FIG. 5 is a perspective view of an illustrative substrate 10 during the process of electroplating. As shown in FIG. 5, cathode 64 (e.g., one or more metal pins or other metal structures) may contact one or more exposed plating lines 18 on interior surface 20 of opening 16 in substrate 10. During plating, substrate 10 is part of a larger sheet of ceramic material. Following plating, the ceramic sheet is singulated to release substrate 10.

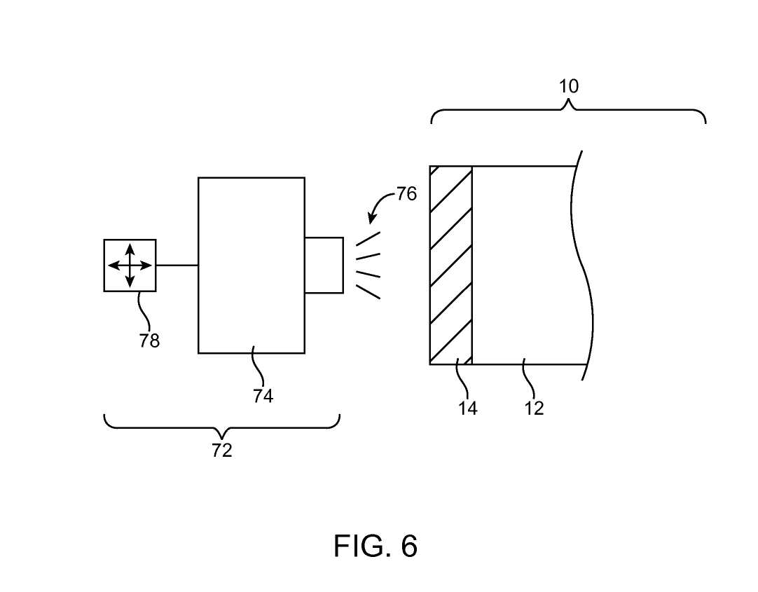

Electromagnetic shielding layer 14 may be formed using electroplating, pad printing, screen printing, painting, dipping, physical vapor deposition, lamination of metal foil, or other suitable techniques for depositing conductive material. As shown in FIG. 6, for example, shielding layer 14 may be formed by ink-jet printing a metal coating such as a layer of metallic paint (e.g., copper paint, silver paint, etc.) onto the outer edge of ceramic material 12 in substrate 10. Layer 14 may be deposited using ink jet printing equipment 72. Printing equipment 72 may include a printing nozzle such as nozzle 74 that emits droplets 76 of metallic paint. Computer-controlled positioner 78 may be used to adjust the position of nozzle 74 relative to substrate 14. During operation, metallic paint 76 may be sprayed onto the edge of ceramic substrate 12 to form an electromagnetic shielding layer such as layer 14 that runs around the entire peripheral edge of substrate 10. In a configuration in which substrate 10 has a rectangular outline with four sides and four corresponding peripheral edge surfaces, layer 14 may coat each of the four peripheral edge surfaces of the dielectric material that makes up substrate 10 (as an example).

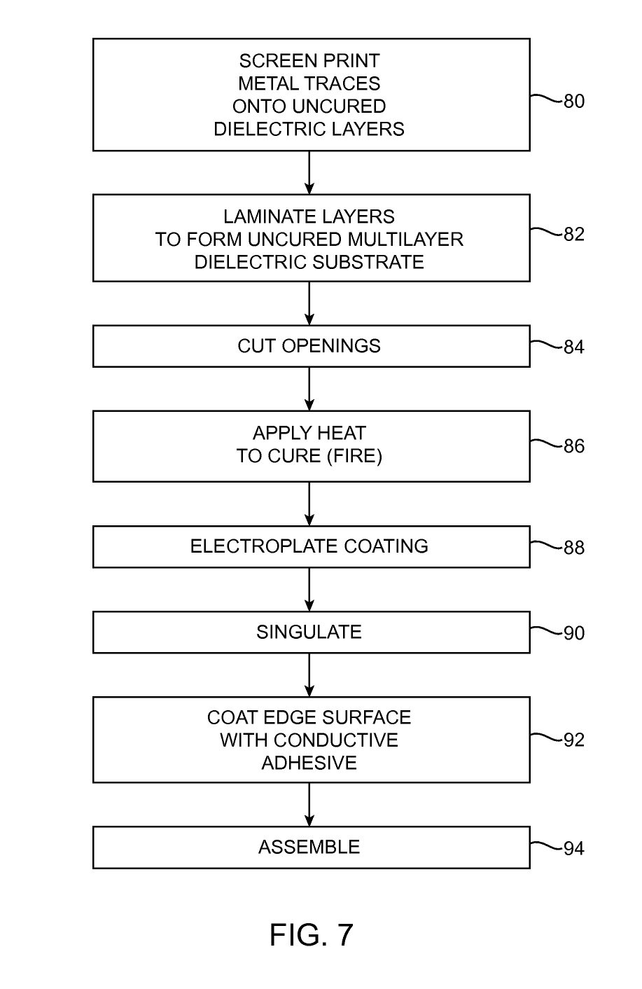

A flow chart of illustrative steps involved in forming substrate 10 is shown in FIG. 7.

At step 80, metal traces are formed on each of the dielectric layers that are to form substrate 10. The dielectric layers may be layers of rigid printed circuit board material (e.g., fiberglass-filled epoxy), layers of flexible printed circuit board substrate (e.g., layers of polyimide), or ceramic layers. The dielectric layers need not be fully cured during the operations of step 80. For example, the rigid printed circuit board layers may not be fully cured and/or the ceramic layers may not be fired. The metal traces may be formed by screen printing metallic paint onto the dielectric layers or using other metal trace formation techniques.

At step 82, the dielectric layers (e.g., the unfired ceramic layers) are laminated together to form a multilayer dielectric substrate structure. The lamination process may be performed using pressure and, if desired, heat (e.g., with rollers, a parallel plate press, etc.). The resulting laminated stack of dielectric layers may form a large sheet of substrate material (e.g., a large sheet of ceramic with metal traces, a large sheet of printed circuit board material with metal traces, a large sheet of polyimide with metal traces, etc.).

At step 84, openings such as opening 16 of FIG. 1 may be formed in the sheet of dielectric. For example, a die press, laser cutting tool, knife cutting tool, or other hole formation equipment may be used in forming an array of openings 16 in the dielectric sheet (e.g., an array of 4 or more openings, an array of 10 or more openings, an array of 100 or more openings, etc.). When the openings such as opening 16 are formed, the inwardly protruding metal traces of each substrate which form internal plating lines on one or more of the metal layers 24 are cut to form exposed plating lines 18. The plating lines may be located on the next-to-uppermost metal layer 24 or on any other suitable metal layer 24 in the dielectric sheet.

At step 86, heat may be applied to the sheet of dielectric. The heat may cure otherwise uncured polymer materials or may fire the ceramic of the unfired ceramic materials.

At step 90, the fired dielectric sheet may be electroplated using equipment of the type shown in FIG. 5. During electroplating, an electrode such as cathode 64 is placed in contact with plating lines 18 in opening 16. This allows plating current to flow that plates metal onto the exposed metal traces on the sheet of dielectric material (e.g., exposed contacts). There may be a cathode for each separate set of plating lines (e.g., for each substrate 10) in the dielectric sheet.

After plating operations are complete, the dielectric sheet may be singulated to form individual substrates such as substrate 10. A saw or other equipment may be used to saw the dielectric sheet into rectangular substrates having four vertically extending peripheral edge surfaces.

At step 92, equipment of the type shown in FIG. 6 or other equipment may be used to apply a conductive coating to the four peripheral edge surfaces of substrate 10, thereby forming electromagnetic shielding for substrate 10.

At step 94, components such as an image sensor or other integrated circuit 36, electrical components 46, and glass layer 44 may be mounted to substrate 10 and substrate 10 may be attached to additional substrates such as printed circuit 30. Solder and other conductive attachment mechanisms may be used in mounting circuitry to substrate 10 and in mounting substrate 10 to printed circuit 30. Following assembly of substrate 10 and printed circuit 30, substrate 10 and printed circuit 30 may be mounted with other components in an electronic device. The electronic device into which substrate 10 and printed circuit 30 are mounted may be a camera, a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment.

The foregoing is merely illustrative and various modifications can be made by those skilled in the art without departing from the scope and spirit of the described embodiments. The foregoing embodiments may be implemented individually or in any combination.

What is claimed is:

1. A dielectric substrate having a rectangular outline and four sides, the dielectric substrate comprising:
metal traces that include a plating line;
dielectric that supports the metal traces; and
an opening in the dielectric having a surface on which the plating line is exposed.

2. The dielectric substrate defined in claim 1 wherein the dielectric comprises ceramic.

3. The dielectric substrate defined in claim 2 wherein the ceramic comprises alumina.

4. The dielectric substrate defined in claim 1 wherein the opening comprises a rectangular opening and wherein the surface comprises an inner edge surface of the rectangular opening.

5. The dielectric substrate defined in claim 4 wherein the metal traces include contacts on the dielectric.

6. The dielectric substrate defined in claim 5 wherein the dielectric comprises ceramic.

7. The dielectric substrate defined in claim 6 further comprising an integrated circuit soldered to the contacts.

8. The dielectric substrate defined in claim 7 wherein the integrated circuit comprises an image sensor that receives light through the opening.

9. The dielectric substrate defined in claim 8 further comprising additional integrated circuits soldered to the contacts.

10. The dielectric substrate defined in claim 6 wherein the ceramic has four peripheral edge surfaces along the four sides and wherein the dielectric substrate further comprises a conductive coating on the peripheral edge surfaces.

11. The dielectric substrate defined in claim 1 wherein the dielectric has four peripheral edge surfaces along the four sides, the dielectric substrate further comprising a conductive coating on the peripheral edge surfaces.

12. The dielectric substrate defined in claim 11 wherein the conductive coating comprises a metal electromagnetic interference shield.

13. The dielectric substrate defined in claim 12 wherein the dielectric comprises a plurality of laminated ceramic layers.

14. The dielectric substrate defined in claim 12 wherein the dielectric comprises rigid printed circuit board material.

15. The dielectric substrate defined in claim 14 wherein the rigid printed circuit board material comprises epoxy.

16. A ceramic circuit carrier, comprising:
a ceramic structure containing multiple ceramic layers and metal traces, wherein the ceramic structure comprises four peripheral edge surfaces; and
a metal coating on the four peripheral edge surfaces.

17. The ceramic circuit carrier defined in claim 16 wherein the ceramic structure is a rectangular ring-shaped ceramic structure having a central opening with inner edge surfaces.

18. The ceramic circuit carrier defined in claim 17 wherein the metal traces include electroplating lines that have exposed portions at the inner edge surfaces.

19. Apparatus, comprising:
a rectangular ring-shaped dielectric structure having multiple dielectric layers supporting metal traces, wherein the rectangular ring-shaped dielectric structure has an opening with an inner edge surface; and
electroplating lines that are exposed on the inner edge surface.

20. The apparatus defined in claim 19 wherein the rectangular ring-shaped dielectric structure has four peripheral edge surfaces, the apparatus further comprising an electromagnetic shielding layer on the four peripheral edge surfaces.
